(19) United States
(12) Patent Application Publication
(10) Pub. No.: US 2022/0390828 A1
(43) Pub. Date: Dec. 8, 2022

(54) METHOD OF MAKING MASK PATTERN AND METHOD OF FORMING PATTERN IN LAYER

(71) Applicant: UNITED MICROELECTRONICS CORP., Hsin-Chu City (TW)

(72) Inventors: Pin-Han Huang, Tainan City (TW); Chih-Wei Hsu, Tainan City (TW)

(21) Appl. No.: 17/341,342

(22) Filed: Jun. 7, 2021

(51) Int. Cl. G03F 1/36

(52) U.S. Cl. CPC G03F 1/36

(57) ABSTRACT

A method of making mask patterns includes the following steps. A first octagon feature is created, wherein the first octagon feature includes first sides, second sides orthogonal to the first sides, and third sides, wherein each of the third sides connects the corresponding first side to the corresponding second side. An optical proximity correction (OPC) process is applied by using a computer to parallel shift the first sides, the second sides and the third sides of the first octagon feature respectively, and thus to create a second octagon feature. The second octagon feature is applied to make a pattern of a photomask. A method of forming a pattern in a layer is also provided, which includes printing a circular pattern on a surface of a layer by using an octagon pattern of a photomask.

### BACKGROUND OF THE INVENTION

### 1. Field of the Invention

The present invention relates generally to a method of making mask patterns and a method of forming a pattern in a layer, and more specifically to a method of making mask patterns and a method of forming a pattern in a layer applying an optical proximity correction (OPC) process.

### 2. Description of the Prior Art

Optical proximity correction or OPC is a photolithography enhancement technique commonly used to compensate for image errors due to diffraction or process effects. The need for OPC is seen mainly in the making of semiconductor devices and is due to the limitations of light to maintain the edge placement integrity of the original design, after processing, into the etched image on the silicon wafer. These projected images appear with irregularities such as line widths that are narrower or wider than designed, these are amenable to compensation by changing the pattern on the photomask used for imaging. Other distortions such as rounded corners are driven by the resolution of the optical imaging tool and are harder to compensate for. Such distortions, if not corrected for, may significantly alter the electrical properties of what was being fabricated. Optical Proximity Correction corrects these errors by moving edges or adding extra polygons to the pattern written on the photomask. The objective is to reproduce, as well as possible, the original layout drawn by the designer in the silicon wafer.

### SUMMARY OF THE INVENTION

The present invention provides a method of making mask patterns and a method of forming a pattern in a layer, which creates an octagon feature and parallel shifts edges of the octagon feature using optical proximity correction (OPC) methods by using a computer, to provide an octagon pattern of a photomask and thus a circular pattern can be printed in a layer by the octagon pattern of the photomask. This reduces convergence time and make the printed pattern more symmetric.

The present invention provides a method of making mask patterns including the following steps. A first octagon feature is created, wherein the first octagon feature includes first sides, second sides orthogonal to the first sides, and third sides, wherein each of the third sides connects the corresponding first side to the corresponding second side. An optical proximity correction (OPC) process is applied by using a computer to parallel shift the first sides, the second sides and the third sides of the first octagon feature respectively, and thus to create a second octagon feature. The second octagon feature is applied to make a pattern of a photomask.

The present invention provides a method of forming a pattern in a layer, including printing a circular pattern on a surface of a layer by using an octagon pattern of a photomask.

According to the present invention provides a method of making mask patterns and a method of forming a pattern in a layer, which creates a first octagon feature, applies an optical proximity correction (OPC) process by using a computer to parallel shift the sides of the first octagon feature to create a second octagon feature, and then applies the second octagon feature to make a pattern of a photomask. By doing this, processes can be simplified since steps of dividing the first octagon feature into segments and calculating these segments respectively can be omitted. This saves times to calculate edges of the first octagon feature, reduces convergence time and makes a pattern printed by the pattern of the photomask more symmetric.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 schematically depicts a flowchart of a method of making mask patterns according to an embodiment of the present invention.

FIG. 2 schematically depicts a diagram of making mask patterns according to an embodiment of the present invention.

FIG. 3 schematically depicts a flow chart of a method of forming a pattern in a layer according to an embodiment of the present invention.

### DETAILED DESCRIPTION

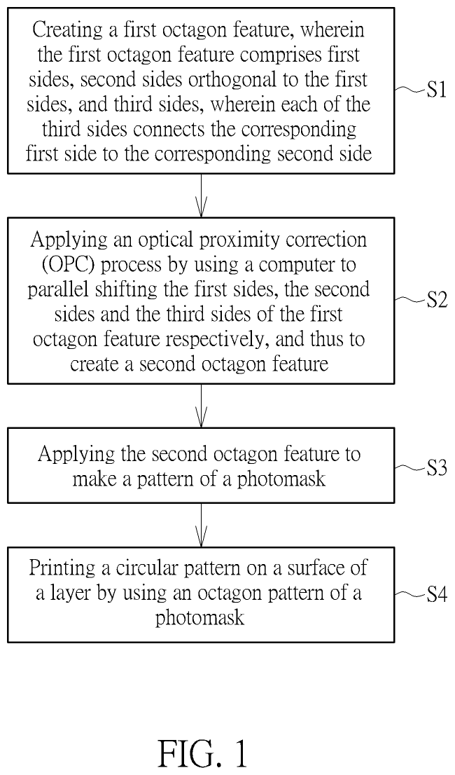

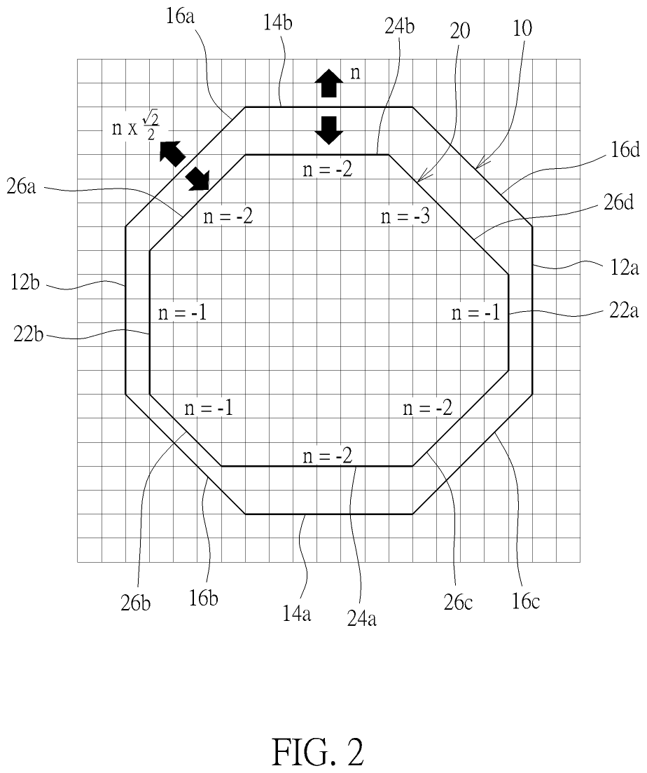

FIG. 1 schematically depicts a flowchart of a method of making mask patterns according to an embodiment of the present invention. FIG. 2 schematically depicts a diagram of making mask patterns according to an embodiment of the present invention. An optical proximity correction (OPC) process is applied for making mask patterns. According to a step S1 of FIG. 1—creating a first octagon feature, wherein the first octagon feature comprises first sides, second sides orthogonal to the first sides, and third sides, wherein each of the third sides connects the corresponding first side to the corresponding second side, a first octagon feature 10 is created, as shown in FIG. 2. The first octagon feature 10 is created in accordance with square units in this embodiment. The square units correspond to rectangular beam shots of electron beam (E-beam) writing for printing the mask patterns onto a layer of a substrate or a wafer, but it is restricted thereto. The first octagon feature 10 includes two first sides 12a/12b, two second sides 14a/14b and four third sides 16a/16b/16c/16d. The second sides 14a/14b are orthogonal to the first sides 12a/12b, and each of the third sides 16a/16b/16c/16d connects the corresponding first side 12a/12b to the corresponding second side 14a/14b. In this case, the first sides 12a/12b extend along y axis, the second sides 14a/14b extend along x axis, and the slop of each of the third sides 16a/16b/16c/16d is +1 or −1. In this embodiment, the first octagon feature has a regular octagon shape, but it is not limited thereto.

According to a step S2 of FIG. 1—applying an optical proximity correction (OPC) process by using a computer to parallel shift the first sides, the second sides and the third sides of the first octagon feature respectively, and thus to create a second octagon feature, an optical proximity correction (OPC) process is processed to create a second octagon feature 20 from the first octagon feature 10, as shown in FIG. 2. Each of the first sides 12a/12b, each of the second sides 14a/14b and each of the third sides 16a/16b/16c/16d of the first octagon feature 10 are shifted in the present invention. Preferably, each of the first sides 12a/12b, each of the second sides 14a/14b and each of the third sides 16a/16b/16c/16d are shifted individually to approach a desired octagon feature. By creating the first octagon feature 10 and then creating the second octagon feature 20 from parallel shifting sides of the first octagon feature 10 to approach a desired mask pattern, processes can be simplified since steps of dividing the first octagon feature 10 into segments and calculating these segments to approach parts of the desired mask pattern respectively can be omitted, thereby saving times for calculating edges of the first octagon feature 10, reducing convergence time and making a printed pattern by the desired mask pattern more symmetric.

Still preferably, each of the first sides 12a/12b are shifted with n1 times of a unit pitch p, each of the second sides 14a/14b are shifted with n2 times of the unit pitch p, and each of the third sides 16a/16b/16c/16d are shifted with n3×√2/2 times of the unit pitch p, wherein n1, n2, n3 is integer. In this embodiment, the unit pitch p is a width of a rectangular beam shot, but it is not limited thereto. The integer of n1, n2, n3 is according to features close to each of the first sides 12a/12b, the second sides 14a/14b and the third sides 16a/16b/16c/16d, or/and the integer of n1, n2, n3 is according to exposure parameters while printing the pattern of the photomask applied by the second octagon feature 20 to a layer in later processes.

In this case, the second octagon feature 20 is an internal shrinkage octagon feature of the first octagon feature 10, but the present invention is not restricted thereto. For example, the first sides 12a/12b are both shifted with n1=−1 times of the unit pitch p, the second sides 14a/14b are both shifted with n2=−2 times of the unit pitch p, and the third side 16a is shifted with (n3=−2)×√2/2 times of the unit pitch p, the third side 16b is shifted with (n3=−1)×√2/2 times of the unit pitch p, the third side 16c is shifted with (n3=−2)×√2/2 times of the unit pitch p, and the third side 16d is shifted with (n3=−3)×√2/2 times of the unit pitch p. Thus, the second octagon feature 20 is obtained.

The second octagon feature 20 obtained by parallel shifting sides of the first octagon feature 20 also has two first sides 22a/22b, two second sides 24a/24b and four third sides 26a/26b/26c/26d, wherein the first sides 22a/22b extend along y axis, the second sides 24a/24b extend along x axis, and the slop of each of the third sides 26a/26b/26c/26d is +1 or −1. Hence, a pattern of a photomask produced by the second octagon feature 20 can be more symmetric.

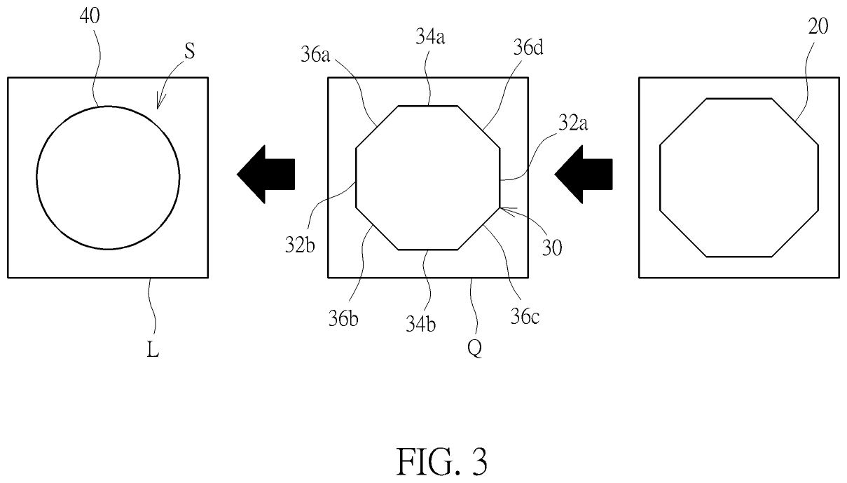

FIG. 3 schematically depicts a flow chart of a method of forming a pattern in a layer according to an embodiment of the present invention. According to a step S3 of FIG. 1—applying the second octagon feature to make a pattern of a photomask, the second octagon feature 20 is applied to make a pattern 30 of a photomask Q. The pattern 30 of the photomask Q is also an octagon pattern due to the second octagon feature 20, wherein the (octagon) pattern 30 may include two first sides 32a/32b, two second sides 34a/34b and four third sides 36a/36b/36c/36d. The second sides 34a/34b are orthogonal to the first sides 32a/32b, and each of the third sides 36a/36b/36c/36d connects the corresponding first side 32a/32b to the corresponding second side 34a/34b.

Since the first sides 22a/22b of the second octagon feature 20 extend along y axis, the second sides 24a/24b of the second octagon feature 20 extend along x axis, and the slop of each of the third sides 26a/26b/26c/26d of the second octagon feature 20 is +1 or −1, the first sides 32a/32b also extend along y axis, the second sides 34a/34b extend along x axis, and the slop of each of the third sides 36a/36b/36c/36d is +1 or −1.

By using the (octagon) pattern 30 of the photomask Q, a pattern 40 is printed on a surface S of a layer L. The surface S of the layer L may be a surface of a wafer. In the present invention, the pattern 40 is a circular pattern printed by the (octagon) pattern 30 of the photomask Q.

To summarize, the present invention provides a method of making mask patterns and a method of forming a pattern in a layer, which creates a first octagon feature, applies an optical proximity correction (OPC) process by using a computer to parallel shift sides of the first octagon feature to create a second octagon feature, and then applies the second octagon feature to make a pattern of a photomask. By doing this, processes can be simplified since steps of dividing the first octagon feature into segments and calculating these segments respectively can be omitted. This saves times to calculate edges of the first octagon feature, reduces convergence time and makes a pattern printed by the pattern of the photomask more symmetric.

Moreover, the pattern of the photomask is an octagon pattern, and a pattern on a layer printed by the octagon pattern of the photomask is a circular pattern. The optical proximity correction (OPC) process is applied to parallel shift first sides, second sides and third sides of the first octagon feature, to create the second octagon feature, wherein the first sides may extend along y axis, the second sides extend along x axis, and the slop of each of the third sides is +1 or −1, to make the printed pattern more symmetric.

Furthermore, each of the first sides are shifted with n1 times of a unit pitch, each of the second sides are shifted with n2 times of the unit pitch, and each of the third sides are shifted with n3×√2/2 times of the unit pitch, wherein n1, n2, n3 is integer, and the unit pitch may be a width of a rectangular beam shot, but it is not limited thereto.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of making mask patterns, comprising:
creating a first octagon feature, wherein the first octagon feature comprises first sides, second sides orthogonal to the first sides, and third sides, wherein each of the third sides connects the corresponding first side to the corresponding second side;
applying an optical proximity correction (OPC) process by using a computer to parallel shift the first sides, the second sides and the third sides of the first octagon feature respectively, and thus to create a second octagon feature; and
applying the second octagon feature to make a pattern of a photomask.

2. The method of making mask patterns according to claim 1, wherein the first sides extend along y axis, and the second sides extend along x axis.

3. The method of making mask patterns according to claim 2, wherein the slop of each of the third sides is +1 or −1.

4. The method of making mask patterns according to claim 1, wherein each of the first sides, each of the second sides and each of the third sides are shifted individually.

5. The method of making mask patterns according to claim 1, wherein each of the first sides are shifted with n1 times of a unit pitch, wherein n1 is integer.

6. The method of making mask patterns according to claim 5, wherein each of the second sides are shifted with n2 times of the unit pitch, wherein n2 is integer.

7. The method of making mask patterns according to claim 6, wherein each of the third sides are shifted with n3×√2/2 times of the unit pitch, wherein n3 is integer.

8. The method of making mask patterns according to claim 7, wherein the integer of n1, n2, n3 is according to features close to each of the first sides, the second sides and the third sides.

9. The method of making mask patterns according to claim 7, wherein the integer of n1, n2, n3 is according to exposure parameters while printing the pattern of the photomask to a layer.

10. The method of making mask patterns according to claim 9, wherein a printed pattern on the layer is a circular pattern.

11. The method of making mask patterns according to claim 7, wherein the unit pitch is a width of a rectangular beam shot.

12. The method of making mask patterns according to claim 1, wherein the second octagon feature is an internal shrinkage octagon feature of the first octagon feature.

13. A method of forming a pattern in a layer, comprising:
printing a circular pattern on a surface of a layer by using an octagon pattern of a photomask.

14. The method of forming a pattern in a layer according to claim 13, wherein the octagon pattern comprises first sides, second sides orthogonal to the first sides, and third sides, wherein each of the third sides connects the corresponding first side to the corresponding second side.

15. The method of forming a pattern in a layer according to claim 14, wherein the first sides extend along y axis, and the second sides extend along x axis.

16. The method of forming a pattern in a layer according to claim 15, wherein the slop of each of the third sides is +1 or −1.

17. The method of forming a pattern in a layer according to claim 13, wherein the surface of the layer comprises a surface of a wafer.
